(19) United States
(12) Patent Application Publication
(10) Pub. No.: US 2008/0036039 A1
(43) Pub. Date: Feb. 14, 2008

(54) New Structure for Microelectronics and Microsystem and Manufacturing Process

(75) Inventor: Bernard Aspar, Rives (FR)

Correspondence Address: OBLON, SPIVAK, MCCLELLAND MAIER & NEUSTADT, P.C., 1940 DUKE STREET, ALEXANDRIA, VA, 22314, US

(73) Assignee: TRACIT TECHNOLOGIES, Moirans (FR)

(21) Appl. No.: 11/575,181

(22) PCT Filed: Sep. 27, 2005
(86) PCT No.: PCT/EP05/54854

§ 371 Date: Mar. 13, 2007

Related U.S. Application Data
(60) Provisional application No. 60/673,801, filed on Apr. 22, 2005.

(30) Foreign Application Priority Data
Sep. 30, 2004 (FR) 0452217

(51) Int. Cl. H01L 29/06; H01L 21/30

(52) U.S. Cl. 257/618; 438/459; 257/E29.005; 257/E21.211

(57) ABSTRACT

The invention relates to a process for making a semiconducting structure composed of a surface layer (2), at least one buried layer (4) and a support, comprising: —a first step to make a first layer (44) made of a first material on a first support, and at least one area (26, 28) in this first layer made of a second material with an etching rate greater than the etching rate of the first material, —a second step for the formation of the surface layer (2), by assembly of the structure on a second support, and thinning of at least one of the two supports.

### TECHNICAL DOMAIN AND PRIOR ART

The invention relates to manufacturing of new structures for semiconducting components or MEMS type devices and particularly SOI devices or SOI type devices.

Many MEMS (Micro Electro Mechanical Systems) Microsystems are made using SOI (Silicon On Insulator) materials that in particular can be used to obtain monocrystalline silicon membranes suspended above a cavity.

SOI type materials are structures composed of a surface layer 2 made of monocrystalline silicon on an insulating layer 4, usually a silicon oxide (FIG. 1). For example, these structures are obtained by assembling a silicon wafer 6 oxidized on the surface with another silicon wafer by molecular bonding.

This assembly comprises a step for surface preparation of the two wafers, a step bringing the wafers into contact, and a heat treatment step. Conventionally, this heat treatment is done for 2 h at temperatures typically between 900° and 1250° C.

At least one of the two wafers is then thinned, leaving a thin semiconducting layer 2 on an insulating layer 4.

A thin suspended membrane, for example made of monocrystalline silicon, is sometimes necessary to manufacture some Microsystems.

Component manufacturers often use wafers of SOI materials to obtain such a membrane. They use the surface layer as the active layer to make the devices, and the buried oxide layer as a sacrificial layer.

For example, an opening 12 is made in the surface silicon 2 so that the buried oxide layer 4 can be etched (FIG. 2A).

This buried oxide is usually chemically etched, for example with HF, which causes the formation of a cavity 14 in the layer 4 (FIG. 2B).

The hole 12 can then remain open or it may be closed again (FIG. 2C), for example by deposition of a material (for example silicon). The result is thus a suspended membrane 16 made in the layer 2, and on or in which a microsystem 18 (FIG. 2D) may be made.

It is usually difficult to control etching of the buried layer. In particular, problems may arise during chemical etching, etching solutions may vary as a function of the temperature or the pH, which makes it difficult to control the etched hole and its dimensions.

Another problem that arises with this technique is that it is impossible to make an arbitrarily shaped cavity, for example a square or rectangular or polygonal shaped cavity, in the plane of the layer 2, starting from the circular hole formed by the opening 12.

Chemical etching is isotropic in principle, and is done concentrically about the central hole defined by the opening 12.

It is possible to attempt to use several holes 12 in order to obtain a shape vaguely resembling a rectangle, but it is then very difficult to obtain right angles.

Therefore the problem arises of finding a new process for making suspended membranes and therefore cavities, particularly with technologies using SOI wafers.

The same problem also arises for the manufacture of membranes made of a piezoelectric or pyro-electric or magnetic material above the cavities.

Another problem that arises is to be able to make suspended cavities or membranes in a structure comprising a surface and possibly semiconducting layer, but that may also be a piezoelectric, pyro-electric or magnetic type, a buried layer, and a support or a subjacent layer acting as a support.

Another problem that arises is the mechanical stability of the assembly formed after the cavities have been produced.

Therefore, the problem that arises is to find a new structure of the type including a surface layer, possibly semiconducting, but which may also be of the piezoelectric, pyro-electric or magnetic type, a buried layer and a support or subjacent layer acting as a support, and means of mechanically reinforcing such a structure.

### PRESENTATION OF THE INVENTION

The invention can be used to make a structure composed of a surface layer which in particular may be semiconducting, or of the piezoelectric, or pyroelectric or magnetic type, a buried layer comprising at least one cavity of any shape, and a support or a subjacent layer acting as a support.

The invention relates to a process for making a structure comprising a surface layer, at least one buried layer and a support comprising:
a step to make a first structure, including the formation of at least one first layer made of a first material on a first support, and at least one area in this first layer made of a second material with an etching rate different from the etching rate of the first material,
a step for the formation of the surface layer, by assembly of the first structure with a second support, and possibly thinning of at least one of the two supports.

Therefore, the shape of the area(s) composed of the material with the highest etching rate is defined before the surface layer is formed, so that this shape can be chosen arbitrarily and therefore the shape of the cavity in the buried layer during subsequent etching of this material with a higher etching rate can be determined in advance.

This provides good flexibility with the choice of shapes and relaxes etching conditions of the layer or the area to be etched, or reduces dependence on these conditions.

The buried layer made of a first material contains at least one area composed of at least one second material which is preferably chosen for its behaviour different from the behaviour of the first material with regard to subsequent etching; its etching rate is different from the etching rate of the first material.

Etching, for which the first and second materials have different etching rates, may be done with a reagent. Dry or wet etching may be used. Chemical etching is also possible, for example by HF if an oxide such as SiO₂ is being etched, or by RIE (reactive ionic etching) type etching.

The first step may comprise etching of the first layer to form at least one cavity, followed by deposition of the second material in the cavity(ies) thus formed.

For example, the assembly may be made by molecular bonding or by gluing.

If the assembly is made by molecular bonding, the surfaces may be prepared before they are brought into contact so that their surface properties are compatible with this bonding. For example, a levelling treatment may be applied to achieve good surface properties (roughness, planeness, and few particles, etc.).

Therefore, an intermediate structure is obtained using the process according to the invention, before etching of areas with the highest rate, the area made of a second material being made before two elements to be assembled are brought into contact or assembled.

A process according to the invention may also include a step to produce at least one opening in the surface layer, opening up in the area made from a material with the highest etching rate, then etching of this material to form at least one cavity in the buried layer, this cavity having a predetermined shape as described above.

Therefore, the cavity may have any shape defined by the shape of the area(s) made from the second material, for example a circular or square or rectangular or polygonal or elliptical shape or with at least one right angle in a plane parallel to the plane of the subjacent and surface layers.

Therefore, a process according to the invention is particularly suitable for obtaining membranes suspended at or above buried areas or cavities, occupied by the material with the highest etching rate before etching.

A process according to the invention may also comprise a step for formation of all or part of an electronic or microelectronic or electro-mechanical or MEMS component in the surface layer.

According to one embodiment, the second material has a higher etching rate than the first material.

The surface layer may be made by assembly of the first layer with the second support.

According to another embodiment, the second material has a lower etching rate than the first material.

A step can then be included for the formation of a second uniform layer made of a third material with a lower etching rate than the first material, on the first layer including the first and second materials.

This second layer, and the islands made of the second material remaining after the first material has been etched, will form mechanical resistance and anchorage means for the surface layer.

Furthermore, the second layer may be uniformly levelled more easily than in the previous embodiment in which a levelling step is carried out on an heterogeneous surface in which areas of the first material and areas of the second material are exposed.

According to this second embodiment, the second and third materials may be identical and deposited during the same step.

The first structure with the support, the first layer comprising areas of materials with different etching rates, and the second layer, is then assembled with the second support, the second layer also becoming a buried layer.

A polishing step can then be done before formation of the surface layer, but this step gives a particularly good result when a second layer made of a material with an etching rate lower than the etching rate of the first material, is made on the first buried layer, since levelling is then done on this second buried layer that is uniform.

The invention also relates to a device comprising a surface layer, a buried layer made of a first material, and a support, the buried layer comprising at least one area made of a second material with an etching rate different from the etching rate of the first material.

At least one of the areas made of a second material may have a circular or square or rectangular or polygonal or elliptical shape, or may have at least one right angle in a plane parallel to the plane of the buried and surface layers.

According to one embodiment, the second material has an etching rate greater than the etching rate of the first material.

According to another embodiment, the second material has an etching rate lower than the etching rate of the first material.

A second buried layer may then be provided made of a third material with an etching rate also with a lower etching rate than the first material, the second and third materials possibly being identical.

The invention also relates to a semiconducting device with a surface layer, a buried layer made of a first material and a subjacent layer acting as a support, the buried layer comprising at least one cavity with a square or rectangular or polygonal or elliptical shape or with at least one right angle in a plane parallel to the plane of the buried and surface layers.

It also relates to a semiconducting device with a surface layer, a first buried layer comprising areas made of a first material and at least one cavity, a second buried layer made of a second material and a support.

In a process or a device according to the invention, the first material may for example be made of silicon dioxide or thermal silica or polycrystalline silicon or amorphous silicon or silicon nitride.

For example, the other material may be made of Si₃N₄ or doped silicon oxide of the BPSG or PSG type or SiO₂.

This second material is chosen so that its behaviour when etched is different from the first material. Thus, SiO₂ might be chosen as the material with the lower etching rate for one type of etching, while it will have a higher etching rate for another type of etching.

The buried layer may be composed of silica areas with Si₃N₄ areas, or thermal silica areas with silicon oxide areas of the BPSG or the PSG type.

According to one example, the buried layer is formed from silicon dioxide to be etched and areas made of polycrystalline silicon (for which the etching rate is lower than the etching rate of Si dioxide, particularly for chemical etching with HF), and the second buried layer is also made of polycrystalline Si.

The surface layer may be made of a semiconductor, for example silicon or germanium, or a III-V, II-VI semiconductor or a semiconductor compound for example such as SiGe or a piezoelectric or pyro-electric or magnetic material.

The structure obtained may be an SOI type structure, in other words composed of a semiconducting material and a buried layer with different properties (for example electrical or physical or chemical).

The substrate may also be semiconducting.

### BRIEF DESCRIPTION OF THE FIGURES

FIG. 1 represents an SOI structure.

FIGS. 2A-2D represent steps in a process according to prior art.

FIGS. 3A and 3B represent a component according to the invention, showing a side view and a top view respectively.

FIGS. 4A-4G represent steps in the process according to the invention.

FIGS. 5A-5G represent steps in another process according to the invention.

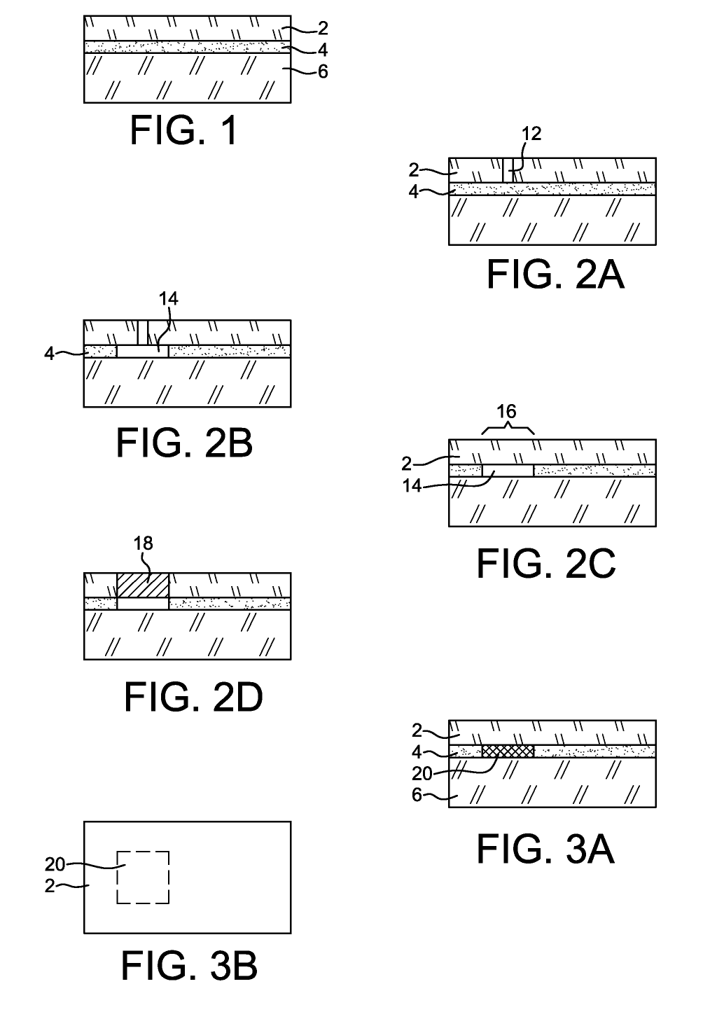

### DETAILED DESCRIPTION OF PARTICULAR EMBODIMENTS

FIG. 3A represents a component according to the invention comprising a buried layer 4 initially made of a first material, and a surface layer 2 for example made of silicon or germanium, or an III-IV semiconductor or an II-VI semiconductor or a semiconductor compound for example such as SiGe, on a substrate 6.

This layer 2 may also be made of a piezoelectric or pyro-electric or magnetic material.

For example, the thickness of layer 4 is between 50 nm and a few μm, for example 10 μm and the thickness of layer 2 is between 10 nm and a few tens of μm, for example 100 μm. These thicknesses may vary outside the ranges indicated.

The buried layer 4 will contain one or several buried areas 20 made of a second material different from the first material in layer 4, the essential difference from layer 4 being in terms of its behaviour during subsequent etching such as dry etching or wet etching; for a given type of etching, the etching rate of the material in area 20 (second material) is higher than the etching rate of the first material and of the material in the surface layer.

In other words, as explained above with reference to FIG. 2A, making an opening 12 will make it possible to preferentially etch this area 20 with an etching rate greater than the etching rate of the material in layer 4. For example, the ratio of the etching rates of the second and first materials is greater than 1 or 2, or is between 2 and 10 or between 10 and 1000 and possibly even more than 1000.

Table I below gives typical example etching rates for some materials and some chemical etching solutions:

TABLE I

| | CHEMICAL ETCHING SOLUTIONS | | | | |
|---|---|---|---|---|---|
| | TMAH 25% | | | | |
| | 80° C. | HF 5% 20° C. | | HF 50% 20° C. | H₃PO₄ 160° C. |
| Si | ˜500 nm/min | <0.5 | nm/min | <1 nm/min | ˜0.2 nm/min |
| SiO₂ | <0.5 nm/min | 20-40 | nm/min | ˜500 nm/min | <0.1 nm/min |
| Si₃N₄ | <0.5 nm/min | ˜0.8 | nm/min | <20 nm/min | ˜5 nm/min |

The area 20 is shown in a side view in FIG. 3A. But as illustrated in FIG. 3B (which is a top view of the component in FIG. 3A), it may be a square in a plane parallel to a principal plane of the component or the layer 4, or it may be any other shape in the same plane: circular, polygonal, elliptical, etc. Therefore, to the extent that etching will act preferentially on the material in this area 20, it will be possible to make an arbitrary shaped cavity, and particularly square or circular or polygonal or elliptical cavity, etc.

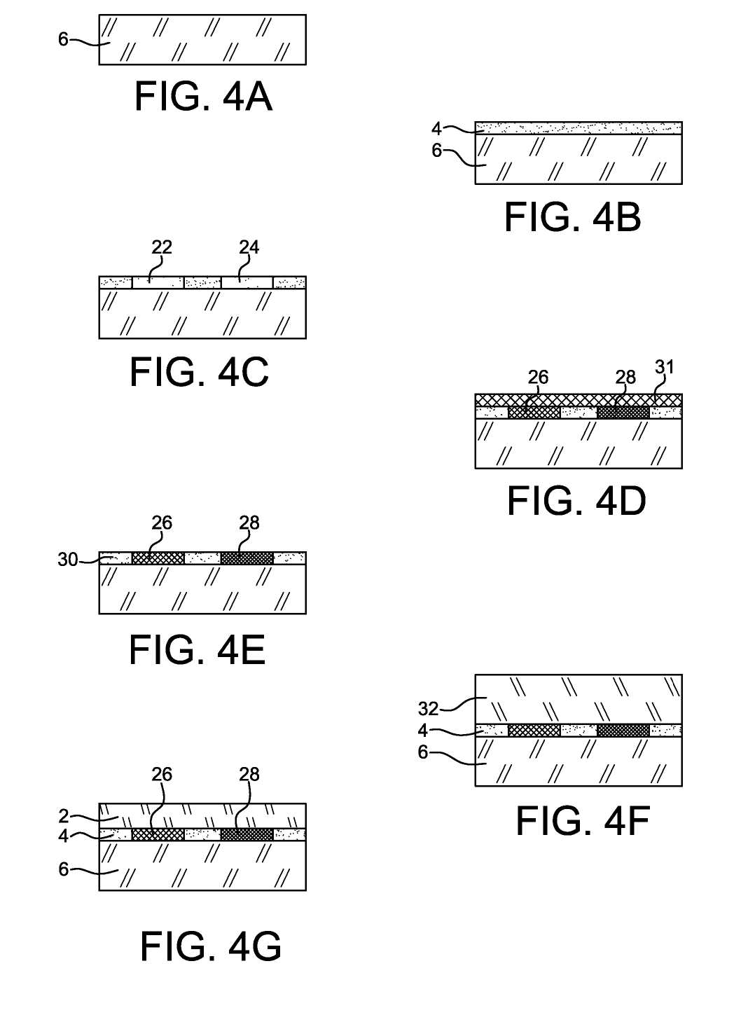

We will now describe a method of making such a component with reference to FIGS. 4A to 4G.

A first layer 4 made of a first material (FIG. 4B), for example an insulating material such as silicon oxide (SiO₂) that can be obtained by thermal oxidation, is made on a blank silicon wafer 6 (FIG. 4A). For example, the thickness of this layer is about 1 μm.

Areas 22 and 24 are defined on this wafer 6 by masking and lithography, and these areas will correspond to the areas of future cavities (FIG. 4C), for example by chemical etching (for example using 10% HF) or RIE etching.

The thermal oxide is etched in these areas so as to completely eliminate this oxide and form these cavities.

A second material 26, 28 (FIG. 4D) is then deposited in these cavities and is etched at rates greater than the etching rates of the thermal oxide 4.

For example, this material may be silicon oxide deposited by CVD which has a different density from the thermal oxide or which has a different chemical composition from the thermal oxide.

This material may also for example be a PSG (Phosphorus doped Spin on Glass) or BPSG (Boron Phosphorus doped Spin on Glass) doped oxide for example with 4% to 6% of P or containing a few % of B.

A material completely different from the oxide in layer 4 could also be used, for example silicon nitride. A H₃PO₄ solution will etch this material preferentially rather than the oxide.

This deposition step may have left a layer or film 31 on the surface. Therefore, the surface 30 of the structure can be levelled (FIG. 4E) so as to have only an alternation of areas made of a first material and areas 26, 28 made of a second material that is more easily etched than the first layer, in the future buried layer, with no layer or film on the surface.

Levelling is preferably such that the surfaces of the two areas formed from the two materials (firstly the material in layer 4 and secondly the material in areas 22, 24), are at the same level with no surface layer 31.

In some cases, a small thickness of a single material (for example 20 nm) may remain on the surface of the entire structure, but this does not create any problem in obtaining the final structure.

This wafer thus prepared is then bonded onto or assembled with another wafer 32 that may for example be made of blank silicon (FIG. 4F).

In one variant, two wafers may be assembled with areas defined on each. For example, the surface of wafer 32 comprises components that have already been made and will come into contact with the areas under which the cavities will be made (on the side that will be assembled with layer 4). In the latter case, the two wafers can be aligned with each other.

The result is then a structure with a “structured” buried layer 4 comprising a support on which there are areas filled with a material 26, 28 that can be etched more easily than the initial material from which the buried layer 4 is made.

According to one variant, at least one of the two wafers 6, 32 may be thinned to obtain a membrane 2 (FIG. 4G) of the required thickness, for example made of monocrystalline silicon.

One of more wafers may be thinned using different means chosen for example from among mechanical thinning and/or mechanical-chemical and/or chemical thinning, and/or thinning by cleavage and/or fracture by heat treatment at a buried plane weakened by the creation of ions (for example hydrogen) or by the creation of porosities. These techniques can be used independently or they may be combined.

Thus, one of the two wafers can be thinned for example by grinding followed by mechanical-chemical polishing to obtain a membrane 2 with a final thickness of 20 μm.

The component or the substrate obtained can be used as an initial material for making a microsystem 18 using the technique described above with reference to FIGS. 2A-2D. Thus, due to the presence of the material 26, 28 in the buried layer, the process for obtaining buried cavities is simpler than in prior art and in particular, can be used to produce much better controlled geometries in the plane of the layer 4, and particularly geometries with any shape such as square or rectangular, or elliptical or any other shape defined by the lithography and etching step of layer 4.

The above description relates to the example of one cavity (FIG. 3A) and two cavities (FIGS. 4D-4G) in layer 4, but any number of cavities with different shapes may be made in the same layer.

Furthermore, two cavities in the same layer may be filled with different materials, these two materials having different etching characteristics from the material in layer 4, and particularly etching rates greater than the etching rate of layer 4.

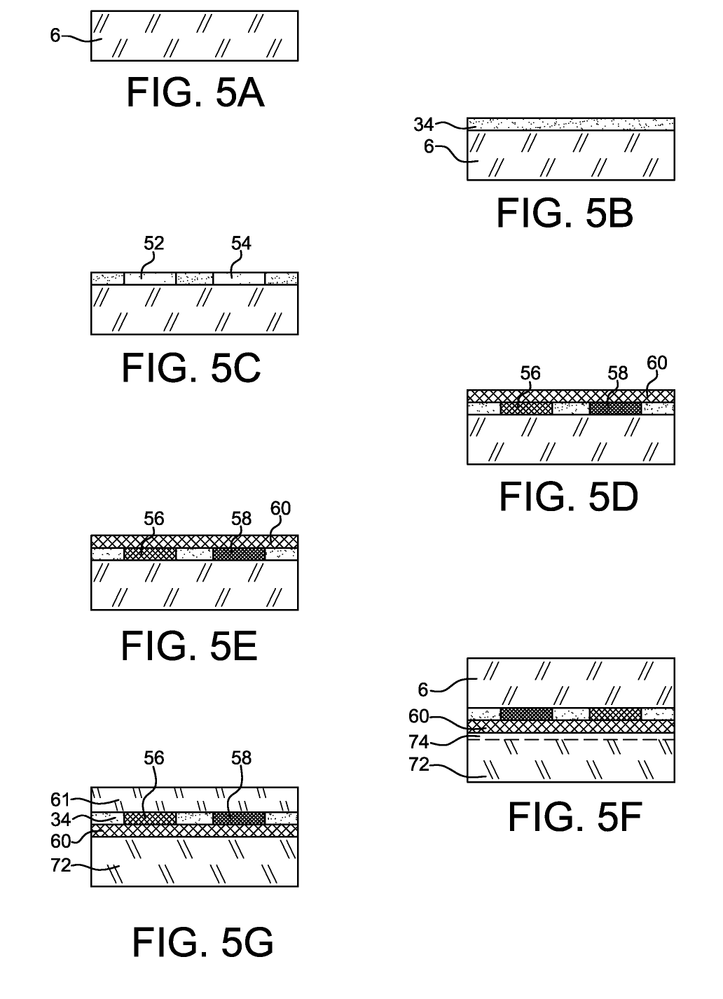

FIG. 5G shows another component according to the invention, consisting of a substrate 72 under a first buried layer 60 and a second buried layer 34 initially made of a first material, and a surface layer 61, for example made of silicon or germanium, or a III-IV or II-VI semiconductor or a semiconductor compound such as SiGe.

This layer 61 may also be made of a piezoelectric or pyro-electric or magnetic material.

For example, the thickness of the layer 34 may be between 50 nm and 500 nm or 1 μm and the layer 61 may be between 10 nm and 1 μm or 50 μm thick. These thicknesses may also vary outside the ranges mentioned above.

The second buried layer 34 comprises one or several buried areas made of a second material 56, 58 different from the first material in layer 34, the essential difference being the behaviour during a subsequent etching operation such as dry etching or wet etching; the etching rate of material 56, 58 is lower than the etching rate of the material in layer 34, which is itself greater than the etching rate of the layer 61.

In other words, production of one or several openings 12 as described above with reference to FIG. 2A, will make it possible to preferentially etch the first material which initially formed the layer 34 with an etching rate greater than the etching rate of the material 56, 58. For example, the ratio of the etching rates of the first material and the second material 56, 58 is greater than 1 or 2, or is between 2 and 10 or between 10 and 1000 and possibly even more than 1000.

Table I above gives typical etching rates for a few materials and for some chemical etching solutions.

The areas outside areas containing the second material 56, 58 are shown as a side view in FIG. 5G. But, as illustrated in FIG. 3B, their shape may be square in a plane parallel to a principal plane of the component or the layer 34, or they may have any other shape (circular, polygonal, elliptical, etc.) in the same plane. Since etching will act preferentially on the material other than material 56, 58, therefore it will be possible to make cavities of any shapes and particular square or circular or polygonal or elliptical cavities, etc.

The second buried layer 60 is composed of the same material as the material 56, 58 or another material but also with an etching rate lower than the etching rate of the first material in the layer 34.

Therefore, etching of this first material in layer 34 will leave anchor pads of material 56, 58 and a subjacent layer 60. These pads and the layer 60 provide mechanical anchorage and stability for the surface layer 61 on the substrate 72. Therefore, these means increase the solidity of the assembly.

A process for making such a component will now be described with reference to FIGS. 5A to 5G.

A first layer 34 made of a first material, for example an insulating material (FIG. 5B) for example silicon oxide (SiO₂) for example obtained by thermal oxidation or LPCVD or PECVD, is made on a blank silicon wafer (FIG. 5A). For example, the thickness of this layer may be about 1 μm.

Areas 52, 54 are defined on this wafer 6 by lithography, and these areas will define the areas of future cavities (FIG. 5C), for example by chemical etching (for example by 10% HF) or RIE etching.

The material 34 is etched in these areas so as to completely eliminate it and to form these cavities.

The second material 56, 58 is then deposited in these cavities (FIG. 5D) and this material is etched at rates lower than the etching rate of the first material 34.

This second material 56, 58 may for example be silicon nitride or polycrystalline Si if the layer 34 or the first material from which it is made is a silicon oxide SiO₂. This second material is chosen so that it behaves differently than the first material, particularly while etching during which gases or the solution preferentially etch the silicon oxide.

This deposition step is continued so as to leave a surface layer or film 60, that can then be levelled (FIG. 5E), for example by mechanical-chemical polishing or using one of the levelling techniques already mentioned above.

Therefore, this film 60 may also be made of polycrystalline Si if the second material 56, 58 is already made of Si-poly.

Note that the material from which the layer 60 is made may be different from the material(s) 56, 58, but its etching rate will be lower than the etching rate of the first material 34.

Levelling then takes place on a uniform surface and therefore under optimum conditions, unlike the case described above with reference to FIG. 4^{E} in which it takes place on a surface composed of two materials with different mechanical properties related to polishing.

Therefore, at the end of levelling there will be a layer 60 made of the second material.

This wafer thus prepared is then bonded onto or is assembled with another wafer 72 that may for example be made of blank silicon (FIG. 5F).

A bonding layer 74 may previously have been deposited either on the substrate 72 or on the layer 60.

Molecular bonding between substrate 72 and the surface of the layer 60 will benefit from optimum levelling made on a uniform surface as described above. The layer 60 then becomes a buried layer.

In one variant, two wafers can be assembled with areas defined on each. For example, there are components on the surface of wafer 72 that have already been made and will come into contact with facing areas on which pads are to be made (on the side that will be assembled with the layer 60). In the latter case, the two wafers can be aligned with each other.

The result is then a structure including a “structured” buried layer 34, comprising areas filled with a first material that can be etched more easily than the second material 56, 58 and more easily than the material from which the second layer 60 is made.

At least one of the two wafers 6, 72 may be thinned to obtain a membrane 61 (FIG. 5G) with the required thickness, for example made of monocrystalline silicon.

One or more wafers may be thinned by different means chosen from among the means already mentioned as examples above.

The component or the substrate obtained may act as an initial material for making a micro-system in layer 61, using the technique described above with reference to FIGS. 2A-2D. Thus, due to the presence of material 56, 58 in the buried layer 34, the process for obtaining buried cavities is simpler than in prior art and can be used to obtain much better controlled geometries in the plane of layer 34, and particularly with any shape, circular or square or rectangular or elliptical, or any other shape defined by the lithography and etching step of layer 34.

Any number of cavities with different shapes can be made in the same layer 34.

Furthermore, two cavities in the same layer may be filled with different materials, these two materials having different etching characteristics compared with the material in layer 34, and particularly their etching rates are lower than the etching rate of the layer 34.

Furthermore, the pads 56, 58 that remain after the first material has been etched provide anchor pads and stability for the resulting device. If they are conducting, they may also provide electrical continuity.

1-38. (canceled)

39. Process for making a structure comprising a surface layer, at least one buried layer and a support, this process comprising:
a first step to make a first structure, including the formation of a first layer made of a first material on a first support, and at least one area in said first layer made of a second material with an etching rate different from an etching rate of said first material,
then a second step for the formation of the surface layer, by assembly of said first structure with a second support.

40. Process according to claim 39, also comprising thinning of at least one of said two supports.

41. Process according to claim 39, comprising etching of said first layer to form at least one cavity, followed by deposition of said second material in said at least one cavity.

42. Process according to claim 39, said assemble being made by molecular bonding or by gluing.

43. Process according to claim 39, also including a step to produce at least one opening in the surface layer, opening up in the material of the buried layer with the highest etching rate.

44. Process according to claim 43, also including etching of the material with the highest etching rate, to form at least on cavity in the buried layer.

45. Process according to claim 44, said at least one cavity having a circular or square or rectangular or polygonal or elliptical shape or with at least one right angle in a plane parallel to the plane of the subjacent layers and surface layers.

46. Process according to claim 39, the material with the highest etching rate being made of silicon dioxide or thermal silica or polycrystalline silicon or amorphous silicon or silicon nitride.

47. Process according to claim 39, the material with the lower etching rate being made of Si₃N₄ or doped silicon dioxide of the BPSC or PSG type or SiO₂.

48. Process according to claim 39, said surface layer being made of a semiconductor, for example silicon or geranium or a III-V, II-VI semiconductor or a semiconductor compound for example SiGe.

49. Process according to claim 39, said surface layer being made of a piezoelectric or pyro-electric or magnetic material.

50. Process according to claim 39, also comprising a step for formation of at least a part of an electronic or microelectronic or electromechanical or MEMS component in said surface layer.

51. Process according to claim 39, said second material having an etching rate greater than the etching rate of said first material.

52. Process according to claim 51, the surface layer being made by assembly of said first layer with said second support.

53. Process according to claim 39, said second material having an etching rate lower than the etching rate of said first material.

54. Process according to claim 53, also comprising a step for formation of a second layer made of a third material with a lower etching rate than the etching rate of said first material, on said first layer including said first and second materials.

55. Process according to claim 54, said second and third materials being identical and being deposited during the same step.

56. Process according to claim 53, said surface layer being made by assembly of said second layer with said second support.

57. Process according to claim 39, also comprising a polishing step before formation of said surface layer.

58. Process according to claim 39, a side of the surface of said second support to be assembled with said first layer comprising components that will come into contact with said at least one area in said first layer, both wafers being aligned with each other when assembling said first structure with said second support.

59. Device comprising a blank surface layer, at least one buried layer made of a first material, and a support, said buried layer comprising at least one area made of a second material, with an etching rate different from an etching rate of said first material.

60. Device according to claim 59, at least one area made of a second material having a circular or square or rectangular or polygonal or elliptical shape or at least one right angle in a plane parallel to the plane of the buried layer and surface layer.

61. Device according to claim 59, the material with the lower etching rate being an electrical insulator such as silicon dioxide, or thermal silica or polycrystalline silicon or amorphous silicon or silicon nitride.

62. Device according to claim 59, the material with the highest etching rate being made of Si₃Ni₄ or doped silicon dioxide of the BPSC or PSG type or Si₂O₂.

63. Device according to claim 59, said surface layer being made of a semiconductor, of silicon or germanium, or III-V or II-VI semiconductor or a semiconductor compound of SiGe.

64. Device according to claim 59, said surface layer being made of a piezoelectric, or pyro-electric magnetic material.

65. Device according to claim 59, said second material having an etching rate higher than the etching rate of said first material.

66. Device according to claim 59, said second material having an etching rate lower than the etching rate of said first material.

67. Device according to claim 66, also comprising a second buried layer made of a third material with an etching rate lower than the etching rate of said first material.

68. Device according to claim 67, said second and third materials being identical.

69. Device according to claim 59, a ratio of the highest etching rate to the lowest etching rate being greater than 10.

70. Semiconducting device comprising:
a surface layer
a first buried layer comprising areas made of a first material and at least one cavity with a square or rectangular or polygonal or elliptical shape or with at least one right angle in a plane parallel to the plane of the buried layer and layer surface,
a second buried layer made of a second material
and a support.

71. Device according to claim 70, said surface layer being made of a semiconductor, of silicon or germanium or a III-V or II-IV semiconductor or a semiconductor compound of SiGe.

72. Device according to claim 70, said surface layer being made of a piezoelectric, or pyro-electric or magnetic material.

73. Device according to claim 70, also comprising all or part of an electronic or microelectronic or electromechanical or MEMS component in said surface layer, above said cavity formed in said buried layer.

74. Device comprising a surface layer, at least one buried layer, made of a first material, and a support, said at least one buried layer comprising at least two areas, one made of a second material, another one made of a third material, different from said second material, said second and third materials having etching rates different from the etching rate of said first material, a second buried layer made of a material having an etching rate lower than the etching rate of said first material.

75. Device according to claim 74, said second and third materials having etching rates greater than the etching rate of said first material.

76. Device according to claim 74, said second and third materials having etching rates lower than the etching rate of said first material.
